(19) United States
(12) Patent Application Publication
(10) Pub. No.: US 2015/0108429 A1
(43) Pub. Date: Apr. 23, 2015

(54) CARBON NANOTUBE PRINTED ELECTRONICS DEVICES

(71) Applicant: Harsha Sudarsan Uppili, Portland, OR (US)

(72) Inventor: Harsha Sudarsan Uppili, Portland, OR (US)

(21) Appl. No.: 14/060,430

(22) Filed: Oct. 22, 2013

(51) Int. Cl. H01L 29/12; H01L 29/66; H01L 21/02; H01L 29/786

(52) U.S. Cl. CPC H01L 29/125; H01L 29/78696; H01L 29/66431; H01L 21/02527; H01L 21/02422; H01L 21/02628
USPC 257/20; 438/151

(57) ABSTRACT

Electronic devices include a network of purified and randomly aligned carbon nanotubes. The electronic devices include conductive regions that comprise conductive inks, and substrates such as flexible plastic materials including PET. Networks of randomly aligned carbon nanotubes are exposed to UV radiation to convert metallic carbon nanotubes to semiconductive carbon nanotubes. Conductive regions are printed onto a substrate using printing techniques such as inkjet printing and gravure printing. Devices are fabricated at low temperatures, without annealing and without vacuum.

### FIELD

This disclosure pertains to methods and apparatus for fabricating carbon nanotube transistors using printed electronics.

### BACKGROUND

Various printing techniques have the potential to reduce cost of production for certain electronic systems. For example, production costs for large area electronics systems can sometimes be reduced by using inkjet printers. However, printed transistors (e.g., organic printed transistors) typically exhibit unfavorably low operating currents due to poor electron and hole mobility as compared to conventional silicon transistors. Also, these transistors can sometimes require high voltage power supplies for operation (e.g., greater than 30 Volts). Consequently, conventional printed transistors are often unattractive for low power applications, which are typical for printed electronics systems.

Additionally, conventional transistors on flexible substrates typically require process steps to be performed at high temperatures (e.g., greater than ambient room temperature, such as greater than 30° C., and sometimes greater than 100° C.), in a vacuum, and/or in conjunction with expensive printers (e.g., greater than $50,000). Further, highly corrosive chemicals such as adhesion promoters are often required.

Therefore, although printing of electronics can provide a lower cost platform for making transistors, the compromise in performance is often large. Thus, it is desirable to provide new techniques for printed electronics devices for improved performance.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Electronic devices comprise a first conductive region and a second conductive region and a network of purified and randomly oriented carbon nanotubes electrically coupled to the first and the second conductive regions, wherein the network of purified and randomly oriented carbon nanotubes comprises both metallic and semiconductive carbon nanotubes such that greater than about 99 percent of the carbon nanotubes in the network are semiconductive nanotubes. The network of purified and randomly oriented carbon nanotubes can be achieved by treating the network with UV radiation to convert metallic nanotubes into semiconductive nanotubes. In some examples, the network of purified and randomly oriented carbon nanotubes includes between about 99.5 percent and about 99.9 percent semiconductive nanotubes. The first and the second conductive regions can comprise unannealed silver nanoparticle ink.

In some example, the electronic device further comprises a substrate having a top surface and a bottom surface, wherein the first conductive region and the second conductive region are situated on the top surface and separated by a third region and at least a portion of the network of purified and randomly oriented carbon nanotubes is situated within the third region. The substrate can comprise a material selected from the following: a plastic, polyethylene terephthalate (PET), a flexible material, a material having a surface roughness that is between about 1 and 20 times an average diameter of the carbon nanotubes, and an adhesion promoting material.

In some implementations, the first conductive region is a source region, the second conductive region is a drain region, and the third conductive region is a channel region. The electronic device can be a transistor, and the transistor can further comprise a dielectric layer situated on top of the source region, the drain region, and the network of nanotubes, and a gate electrode situated on top of the dielectric layer above the channel region and electrically insulated from the source region and the drain region by the dielectric layer. The dielectric layer can comprise polymide.

In some implementations, a plurality of the electronic devices are arranged in a logic circuit.

Methods of fabricating an electronic device comprise depositing carbon nanotube ink including both metallic and semiconductive carbon nanotubes on a substrate to form a randomly aligned network of carbon nanotubes and applying UV radiation to the randomly aligned network of carbon nanotubes to convert some of the metallic carbon nanotubes into semiconductive carbon nanotubes. In some examples, about 99 percent or less of the network of randomly aligned carbon nanotubes are semiconductive nanotubes before the applying of the UV radiation, and more than about 99 percent of the plurality of randomly aligned carbon nanotubes are semiconductive nanotubes after the applying of the UV radiation.

The methods can further comprise printing a first region using conductive ink, and printing a second region using conductive ink, wherein the randomly aligned network of carbon nanotubes electrically couples the first region to the second region. The printing of the first and the second regions can be performed using an inkjet printer or gravure printing techniques. The printing, the depositing and the applying can be performed in an atmospheric pressure between about 80 kPa and about 105 kPa and at a temperature less than about 100 degrees Celsius.

The methods can further comprise depositing a dielectric layer above the first region, the second region, and the network of randomly aligned carbon nanotubes and depositing a conductive material above the dielectric layer to form a gate electrode electrically insulated from the first and the second regions by the dielectric layer.

In some examples, a resistance of the randomly aligned network of carbon nanotubes between the first and the second regions after the application of the UV radiation is at least two times greater than a resistance of the randomly aligned network of carbon nanotubes between the first and the second regions before the application of the UV radiation.

Devices comprise an adhesion promoting substrate layer and a network of purified and randomly-oriented carbon nanotubes situated on the adhesion promoting substrate layer, wherein the network of purified and randomly oriented carbon nanotubes comprises between about 0.1% and about 0.9% photo-oxidized carbon nanotubes. In some example, the devices further comprise a plurality of pairs of printed source and drain regions comprising conductive ink, each pair of source and drain regions connected to each other by a network of nanotubes formed from the plurality of randomly-oriented carbon nanotubes. The substrate can be a flexible material, polyethylene terephthalate (PET), or a plastic. The devices can contain no layer of adhesion promoter modified material.

The foregoing and other features and advantages will become more apparent from the following detailed description, which proceeds with reference to the accompanying figures.

### BRIEF DESCRIPTION OF THE DRAWINGS

FIG. 1A is a cross-sectional view of a representative carbon nanotube printed electronics device.

FIG. 1B is a cross-sectional view of a representative electronic device including a plurality of carbon nanotube printed electronics devices according to FIG. 1A.

FIG. 2A is a cross-sectional view of a representative carbon nanotube printed electronics device.

FIG. 2B is a cross-sectional view of a representative carbon nanotube printed electronics device.

FIG. 3 is a representative method of fabricating a carbon nanotube printed electronics device.

FIG. 4 is a representative method of fabricating a carbon nanotube printed electronics device.

FIG. 5 is a representative method of fabricating a carbon nanotube printed electronics device.

FIGS. 6A-6F illustrate exemplary stages in the fabrication of a carbon nanotube printed electronics device.

FIG. 7 is an image of exemplary printed source, channel, and drain regions of a carbon nanotube printed electronics device.

FIG. 8 shows resistance data from example carbon nanotube ink soak times, illustrating changes in resistance between the source and drain regions of a carbon nanotube printed electronics device as a function of soak time.

FIG. 9 shows resistance data from example UV radiation exposure times for sample carbon nanotube printed electronics devices.

### DETAILED DESCRIPTION

The following disclosure is presented in the context of representative embodiments that are not to be construed as being limiting in any way. This disclosure is directed toward all novel and non-obvious features and aspects of the various disclosed embodiments, alone and in various combinations and sub-combinations with one another. The disclosed methods, apparatus, and systems are not limited to any specific aspect or feature or combination thereof, nor do the disclosed embodiments require that any one or more specific advantages be present or problems be solved.

Although the operations of the disclosed methods are described in a particular, sequential order for convenient presentation, it should be understood that this manner of description encompasses rearrangement of the operations, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other things and methods.

This disclosure sometimes uses terms like “produce,” “generate,” “select,” “receive,” “exhibit,” and “provide” to describe the disclosed methods. These terms are high-level abstractions of the actual operations that are performed. The actual operations that correspond to these terms may vary depending on the particular implementation and are readily discernible by one of ordinary skill in the art.

The singular forms “a,” “an,” and “the” include the plural forms unless the context clearly dictates otherwise. The term “includes” means “comprises.” Unless the context dictates otherwise, the term “coupled” or “connected” means mechanically, electrically, or electromagnetically connected or linked and includes both direct connections or direct links and indirect connections or indirect links through one or more intermediate elements not affecting the intended operation of the described system.

Certain terms may be used such as “top,” “side,” “front,” “back,” “bottom,” “above,” “over,” “under,” and the like. These terms are used, where applicable, to provide some clarity of description when dealing with relative relationships. But, these terms are not intended to imply absolute relationships, positions, and/or orientations. Similarly, the word “or” is intended to include “and” unless the context clearly indicates otherwise.

Unless otherwise indicated, all numbers expressing quantities of components, percentages, temperatures, times, and so forth, as used in the specification or claims are to be understood as being modified by the term “about” or “approximately.” Accordingly, unless otherwise indicated, implicitly or explicitly, the numerical parameters set forth are approximations that may depend on the desired properties sought and/or limits of detection under standard test conditions/methods. When directly and explicitly distinguishing embodiments from discussed prior art, the embodiment numbers are not approximates unless the word “about” is recited.

In some examples, values, procedures or apparatus are referred to as “lowest,” “best,” “optimum,” “minimum,” “maximum” or the like. Such descriptions are intended to indicate that a selection among many functional alternatives can be made, and such selection need not be better, smaller or otherwise preferable to other selections.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Other features of the disclosure are apparent from the following detailed description and the claims.

Carbon nanotube: As used herein, the terms “carbon nanotube” and the shorthand “CNT” or “nanotube” refer to cylindrical-shaped graphene sheets. The carbon nanotubes are single-walled carbon nanotubes (SWCNT or SWNT). The present disclosure is not limited to any one method by which to produce carbon nanotubes. Rather, any suitable method can be used to produce carbon nanotubes for use in conjunction with methods and apparatus of this disclosure. For example, CNTs can be synthesized using chemical vapor deposition (CVD), laser ablation, arc discharge, enzematic synthesis, or other techniques.

Additionally, electronic properties of carbon nanotubes depend on various properties of the rolled graphene sheet, such as the axis along which the tubes are rolled, the diameter of the tube, the degree of the twist (chirality), and the cutoff the graphene sheet. For example, carbon nanotubes rolled along the diagonal (armchair) of the graphene honeycomb structure tend to exhibit metallic properties, while carbon nanotubes rolled along the “zigzag” tend to exhibit semiconducting properties. Typical production of carbon nanotubes generates a mixture of both metallic and semiconductive nanotubes. Therefore, a plurality of carbon nanotubes can refer to a plurality of metallic carbon nanotubes or a plurality of semiconductive carbon nanotubes or a combination thereof.

Further, any size of carbon nanotube can be used. Carbon nanotube length and diameter can affect the electron/hole mobility and semiconducting properties of the nanotubes. Therefore, the carbon nanotube size can be selected to optimize performance and based on desired properties of the carbon nanotubes.

Suitable carbon nanotubes can have average diameters in the range of about 0.5 nanometer to about 25,000 nanometers (25 microns). Alternatively, suitable carbon nanotubes can have average diameters in the range of about 0.5 nanometer to about 10,000 nanometers, or about 0.5 nanometer to about 5,000 nanometers, or about 0.5 nanometer to about 3,000 nanometers, or about 0.5 nanometer to about 1,000 nanometers, or even about 0.5 nanometer to about 200 nanometers. Alternatively, such carbon nanotubes can have average diameters in the range of about 0.5 nanometer to about 100 nanometers, or about 0.5 nanometer to about 50 nanometers, or about 0.5 nanometer to about 10 nanometers, or about 0.5 nanometer to about 2 nanometers, or even about 1 nanometer to about 2 nanometers. Alternatively, carbon nanotubes can have average diameters of less than 5,000 nanometers, or less than 2,000 nanometers, or less than 500 nanometers, or even less than 100 nanometers. Alternatively, such carbon nanotubes can have average diameters of less than 100 nanometers, or less than about 50 nanometers, or less than 10 nanometers, or even less than about 5 nanometers.

The length of the carbon nanotubes is not critical and any length can be used. For example, carbon nanotubes can have lengths in the range of about 1 nanometer to about 25,000 nanometers (25 microns), or from about 1 nanometer to about 10,000 nanometers, or about 1 nanometer to about 5,000 nanometers, or about 100 nanometers to about 5,000 nanometers, or about 10 nanometers to about 3,000 nanometers, or about 300 nanometers to about 5,000 nanometers, or about 10 nanometers to about 1,000 nanometers, or even about 10 nanometers to about 500 nanometers. Alternatively, the carbon nanotubes can have lengths of at least about 5 nanometers, at least about 10 nanometers, at least about 50 nanometers, at least about 100 nanometers, at least about 300 nanometers, at least about 500 nanometers, at least about 1,000 nanometers, at least about 2,500 nanometers, at least about 5,000 nanometers, at least about 7,500 nanometers, at least about 10,000 nanometers, or even at least about 25,000 nanometers. Still further, the carbon nanotubes can have lengths that would not be considered to be nano-scale lengths.

Transistor: A transistor is a three terminal (e.g., three electrode) device used to amplify or switch electronic signals. A voltage or current applied to one terminal can be arranged to change a voltage or current associated with one or both of the other two terminals. Transistors described herein can be bipolar junction transistors (BJT), field effect transistors (FET), or other types of transistors. In a BJT, the three terminals are referred to as a base, collector and emitter, and the current between the collector and emitter is controlled by the base. In a FET, current between a source region and a drain region is controlled by a gate, and the current flows along a path called a channel that connects the source and drain regions. For ease of explanation, the three terminals of a transistor are referred to herein, without limitation, as a source, drain and gate.

Network of Carbon Nanotubes: A network of carbon nanotubes is an electrically continuous grouping of multiple carbon nanotubes. That is, a network provides a pathway for current flow across a plurality of nanotubes. Nanotube networks vary in density based on the method and techniques used to form them. In general, the denser the network, the more electrical pathways exist across the network, reducing the network resistance. The networks can be two or three-dimensional, and can include nanotubes of substantially the same size or of different sizes.

Carbon nanotube networks can be characterized as either aligned or random based on the relative orientation of the nanotubes that make up the network. This is sometimes referred to as a degree of alignment. In a highly aligned network, the orientation for substantially all nanotubes in the network is the same. In general, the randomness of the network is a consequence of the manner in which the nanotubes are deposited or formed. Carbon nanotubes are typically used in either of two ways, by growing the nanotubes directly on the substrate to be used in the nanotube device, or by solution-based deposition. The former can result in highly aligned networks, whereas the latter produces randomly aligned networks.

Highly aligned networks typically require a well-controlled environment, in which the alignment of the nanotubes on a particular substrate can be controlled during the growth process. For example, such networks can be grown directly on a substrate through CVD processes. Semi-aligned nanotube networks can result from spin-coating (radial alignment), flow-based alignment techniques, coffee-ring methods of deposition (ring-shaped alignment), and dielectrophoresis deposition (DEP). Random networks result from gravure printing and inkjet printing processes, or other techniques in which the nanotubes are in solution or powder form and deposited in some manner on a substrate.

Printed electronics: As used herein, printed electronics refers to methods and techniques used to apply inks or other solutions to surfaces. For example, printed electronics includes stamping or transfer printing, screen printing, gravure printing, sheet-based or roll-to-roll processing, offset printing, lithography and inkjet printing. However, this list is not exhaustive. Although photolithography techniques used to fabricate integrated circuits on silicon wafers can be considered a type of “printing,” unless otherwise specified, printed electronics described herein does not refer to this type of lithography or to any other optical lithography techniques. However, photolithography and optical lithography techniques can be used in addition to or combination with techniques described herein.

In general, a component or device that is formed using printed electronics techniques and methods is referred to as “printed.”

Ink: As used herein, ink refers to a liquid or paste containing at least one type of particle and a carrier material (e.g., a liquid vehicle such as water or an organic solvent). Ink refers to the liquid or paste form as well as the dried form of the liquid or paste ink. Inks can be conductive, semiconductive, or insulating. Inks can contain any type of material. Inks can include nanoparticles and/or nanotubes, metals, organic or inorganic materials, etc. For example, silver nanoparticle ink includes at least silver nanoparticles and a carrier material, such as a stabilizing agent. Inks can include conductive and/or semiconductive materials. For example, a conductive ink is an ink that contains a conductive material or particles. Conductive inks can include metallic nanoparticles or other dissolved metal precursors of conductive metals.

Nanotube ink: A solution containing at least CNTs and a carrier material. The nanotubes in a nanotube ink can be produced in any manner. The nanotubes can be pre-sorted to control the relative proportions of metallic and semiconductive nanotubes in the ink, such as by centrifuge or flow-based sorting. Other sorting techniques can be employed so that inks contain nanotubes having substantially the same length, diameter and/or chirality. Alternatively, the properties for the nanotubes in the ink can be substantially different. Inks containing nanotubes that have been sorted to select for either semiconductive nanotubes or metallic nanotubes are sometimes referred to as purified inks. For example, 99% pure semiconductive nanotube ink indicates that 99% of the nanotubes in the ink are semiconductive nanotubes. Carbon nanotube ink can have any concentration of nanotubes, and can be used in diluted or undiluted form.

UV Radiation: As used herein, UV radiation refers to electromagnetic radiation having a wavelength, average wavelength, or a range of wavelengths between about 100 nanometers and about 500 nanometers, about 200 nanometers and about 400 nanometers, about 200 nanometers and about 300 nanometers, about 250 nanometers and about 400 nanometers, about 200 nanometers and about 250 nanometers, about 365 nanometers and about 400 nanometers, about 220 nanometers and about 270 nanometers, about 230 nanometers and about 260 nanometers, or about 240 nanometers and about 250 nanometers. For example, a source of UV radiation can be a xenon or halogen light source. The light source can be filtered to provide only UV radiation, or the light source can emit a broader spectrum of light, including UV radiation.

The disclosure is illustrated by the following non-limiting Examples.

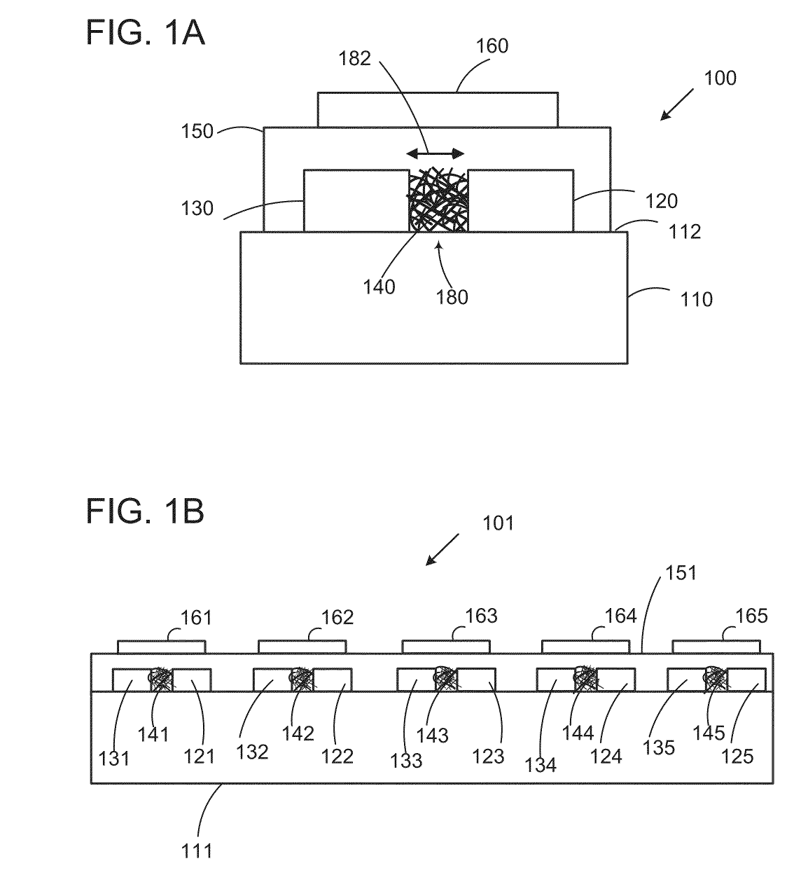

FIG. 1A is a cross-sectional view of a representative carbon nanotube printed electronics device 100. The device 100 includes a substrate 110 having a top surface 112. The substrate 110 can be a variety of different materials. In general, it is preferable that the substrate be compatible with inkjet and/or gravure printing techniques. That is, elements or components of the electronic device 100 can be printed on the substrate 110 using an inkjet printer or other printed electronics techniques described herein.

The substrate 110 is typically made from a flexible material, but it can be rigid, such a glass or silicon substrate. For example, the substrate can be a plastic, such as polyethylene terephthalate (PET), polyethylene naphthalate (PEN) and polyimide (PI). The substrate 110 can be an organic or inorganic material, or a combination of materials. In other examples, the substrate 110 includes a layer of paper, cardboard, foil and/or silicon nanoparticles. For example, the substrate 110 can include a layer of silicon nanoparticles printed or otherwise deposited onto another material.

Preferably, the substrate 110 is not modified with any adhesion promoting solution, and therefore the substrate 110 does not include a layer of adhesion promoter or material modified by any adhesion promoting substance. In some examples, the substrate 110 is an adhesion promoting substrate. That is, the substrate 110 is or includes a layer of adhesion promoting material. For example, the substrate 110 can have a surface roughness that promotes adhesion. For example, the surface roughness of the substrate 110 can be comparable to or larger than the average diameter of carbon nanotubes printed or otherwise deposited onto the surface 112 of the substrate 110. Or, the surface roughness of the substrate 110 can be comparable to or larger than the average diameter of nanoparticles printed or otherwise deposited onto the substrate surface. The substrate 110 can be a material with such surface roughness occurring without additional processing. Or, the substrate 110 can be a material that has been processed to create such surface roughness (e.g., a glass substrate with a roughed surface).

The substrate 110 need not be a material capable of being annealed. Indeed, in some examples, it is preferable that the substrate 110 be a material that does not need to be or is incapable of being annealed at high temperatures, such as at temperatures greater than about 800° C., 600° C., 400° C., 200° C., 150° C., 120° C., 100° C., 80° C., 50° C., 40° C. or 30° C.

Region 130 and region 120 are conductive regions on the substrate 110 separated by a region 180. The region 180 has a length 182. In some examples, region 120 is referred to as a drain region, region 130 is referred to as a source region, and region 180 is referred to as a channel region. Regions 130 and 120 comprise a conductive material. For example, either or both of regions 130 and 120 can comprise a conductive ink, such as silver nanoparticle ink, metallic carbon nanotube ink, gold nanoparticle ink, copper-based nanoparticle ink, palladium nanoparticle ink, platinum nanoparticle ink, or other metallic compound or metallic nanoparticles based ink. For example, the conductive regions 130 and 120 can be formed by printing a conductive ink onto the surface 112 of the substrate 110. In some examples, the conductive material forming region 130 and/or 120 is not annealed.

A network of randomly oriented carbon nanotubes 140 is situated in the region 180. The network 140 is positioned relative to the region 130 and 120 such that the region 130 is electrically coupled by the network 140 to the region 120. The network 140 can comprise carbon nanotube ink and be formed by depositing carbon nanotube ink onto the substrate 110. The network 140 is purified such that greater than about 99 percent of the carbon nanotubes in the network 140 are semiconductive carbon nanotubes. For example, the network 140 can include greater than about 99.1%, 99.2%. 99.3%, 99.4%, 99.5%, 99.6%, 99.7%, 99.8% or 99.9% semiconductive carbon nanotubes. Or, the network 140 can include between about 99.1% and about 99.4%, about 99.2% and about 99.5%, about 99.3% and about 99.6%, about 99.4% and about 99.7%, about 99.5% and about 99.8%, or about 99.6% and about 99.9% semiconductive carbon nanotubes. The network 140 can be purified by exposing a network of randomly oriented carbon nanotubes to UV radiation to convert metallic carbon nanotubes to semiconductive carbon nanotubes as described herein. The concentration of semiconductive carbon nanotubes in the network 140 can be measured through various known methods. For example, the resistance or optical absorption of the network 140 can be measured.

A portion of the nanotubes in the purified network 140 can be photo-oxidized carbon nanotubes. That is, a portion of the carbon nanotubes can include oxygen functionalities, such as in the form of hydoxylic groups or other oxygen-containing groups, attached to the graphene sheet or sidewall of the nanotube. For example, the network 140 can include at least about 0.1%, 0.2%, 0.3%, 0.4%, 0.5%, 0.6%, 0.7% 0.8%, or 0.9% photo-oxidized carbon nanotubes. In other examples, the network 140 includes between about 0.1% and about 0.4%, between about 0.2% and about 0.5%, between about 0.3% and about 0.6%, between about 0.4% and about 0.7%, between about 0.5% and about 0.8%, or between about 0.6% and about 0.9%, or greater than 0.9% photo-oxidized carbon nanotubes. The photo-oxidized carbon nanotubes in the network 140 can be measured through various known methods. For example, the Raman spectra of the network 140 can be measured.

The presence of oxygen-containing groups can be achieved through exposure of the carbon nanotubes to UV radiation, and the photo-oxidized carbon nanotubes can be metallic nanotubes converted into semiconducting nanotubes. For example, the bandgap of a carbon nanotube can determine whether the nanotube is considered metallic or semiconductive. The bandgap is determined by various properties of the nanotubes, such as the chirality and diameter of the nanotube, but the bandgap can also be affected by other characteristics of the nanotube, such as the chemical make-up of the graphene sheet or sidewalls of the nanotube. The presence of oxygen functionalities on the graphene sheet or sidewall of metallic carbon nanotubes can change the bandgap of the nanotubes and make the nanotubes semiconductive. Further, the carbon nanotube size can be selected to enhance the purification process. For example, smaller diameter carbon nanotubes (e.g., less than about 1.3 nanometers) may be more likely to convert from metallic to semiconductive nanotubes (i.e., to become photo-oxidized carbon nanotubes) in the presence of UV radiation.

The size of the carbon nanotubes in the network is typically selected based on the desired properties of the nanotubes. For example, carbon nanotube length and diameter can affect the electron/hole mobility and semiconducting properties of the nanotubes. Therefore, the carbon nanotube size can be selected to optimize performance of the carbon nanotube device.

A dielectric layer 150 is situated on top of or above relative to the conductive regions 120 and 130. The dielectric layer 150 can comprise any dielectric material. For example, the dielectric layer 150 can include epoxy or any polyimide, or a dielectric ink. The dielectric layer 150 can include silicon oxide, ion gel or a high-K dielectric material.

A conductive region 160 is situated on top of or above relative to the dielectric layer 150. In some examples, the conductive region 160 is referred to as a gate electrode. The conductive region 160 can comprise any conductive material. For example, the conductive region 150 can include PEDOT:PSS (poly(3,4-ethylenedioxythiophene) poly(styrenesulfonate)) or other conductive organic polymer. The conductive region 150 can include indium tin oxide, metallic carbon nanotubes or silver. The conductive region 160 can comprise conductive ink. The dielectric layer 150 is situated such that the conductive region 160 is electrically insulated from the conductive regions 120 and 130.

In some examples, the device 100 is a transistor and current through the network 140 between the source region 130 and the drain region 120 is regulated by a voltage applied to the gate electrode 160. Although device 100 is illustrated as a three-terminal device, not all layers and/or terminals (e.g., conductive regions) need be included. For example, the device 100 can be a two-terminal device such as a diode. Furthermore, additional layers and conductive regions can be added to device 100. The device 100 can be part of a logic circuit or other electronic systems. For example, a plurality of devices 100 can be arranged to form a logic circuit.

FIG. 1B is a cross-sectional view of a representative electronic device 101 including a plurality of carbon nanotube printed electronics devices according to FIG. 1A. The device 101 includes a substrate 111, which can be any substrate described herein. The device 101 also includes several conductive regions 131-135 and 121-125. In some examples, the conductive regions 131-135 are referred to as source regions, and the conductive regions 121-125 are referred to as drain regions. The conductive region 131 is electrically connected to the conductive region 121 by network 141 of purified and randomly aligned carbon nanotubes. Likewise, pairs of conductive regions 132 and 122, 133 and 123, 134 and 124, and 135 and 125 are electrically connected to each other by respective networks 142-145 of purified and randomly aligned carbon nanotubes.

The dielectric layer 151 is situated above the conductive regions 131-135, the conductive regions 121-125, and the networks 141-145 such that conductive regions 161-165 are electrically insulated from respective conductive regions 131-135 and 121-125. The conductive regions 161-165 can be referred to as gate electrodes. For example, the device 101 can be five three-terminal devices, such as transistors, connected in a logic circuit, and voltage applied to the individual gate electrodes 161-165 can be used to regulate current between respective source regions 131-135 and drain regions 121-125.

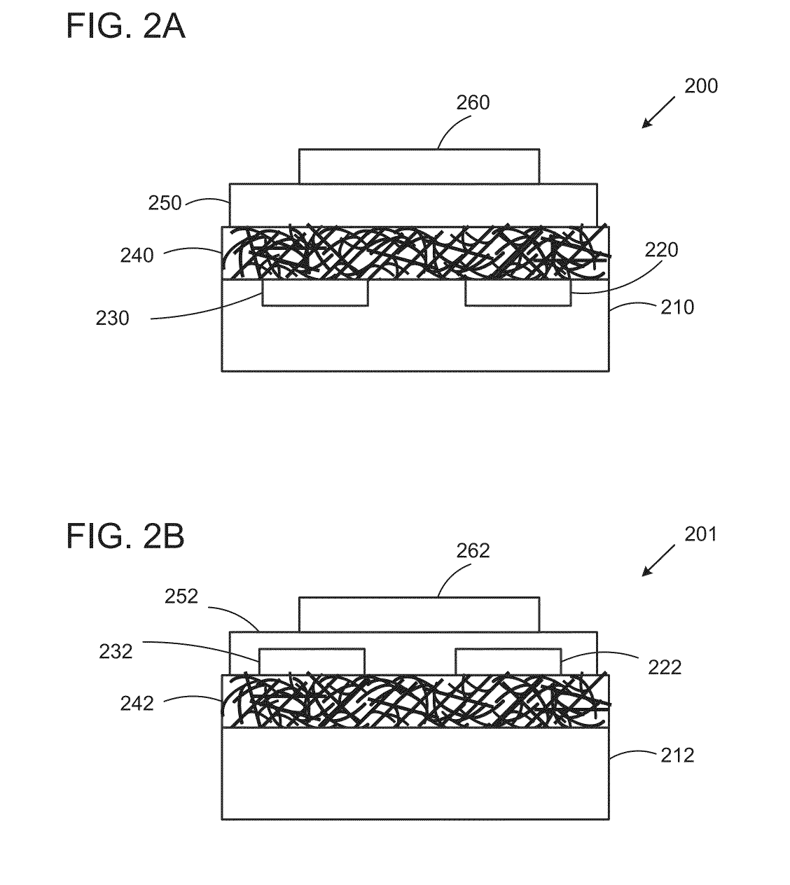

FIG. 2A is a cross-sectional view of a representative carbon nanotube printed electronics device 200. The device 200 includes a substrate 210, which can be any substrate described herein. The substrate 210 includes a first conductive region 230 and a second conductive region 220. In some examples, the conductive region 230 is a source region and the conductive region 220 is a drain region. Above the substrate 210 and the conductive regions 220 and 230 is a layer 240 that includes one or more networks of purified and randomly aligned carbon nanotubes. The layer 240 electrically connects the conductive region 230 to the conductive region 220. A dielectric layer 250 is situated above the layer 240, and electrically insulates the layer 240 from a conductive region 260. The conductive region 260 is referred to in some examples as a gate electrode.

FIG. 2B is a cross-sectional view of a representative carbon nanotube printed electronics device 201. The device 201 includes a substrate 212, which can be any substrate described herein. Above the substrate 212 is a layer 242 that includes one or more networks of purified and randomly aligned carbon nanotubes. A first conductive region 232 and a second conductive region 222 are situated above the layer 242. The first conductive region 232 is electrically connected to the second conductive region 222 by the layer 242. A dielectric layer 252 electrically insulates the conductive region 232 and 222 from a conductive region 262. The conductive region 262 is referred to in some examples as a gate electrode.

Materials and techniques described with regard to FIG. 1A above also apply to the devices illustrated in FIGS. 1B and 2A-2B.

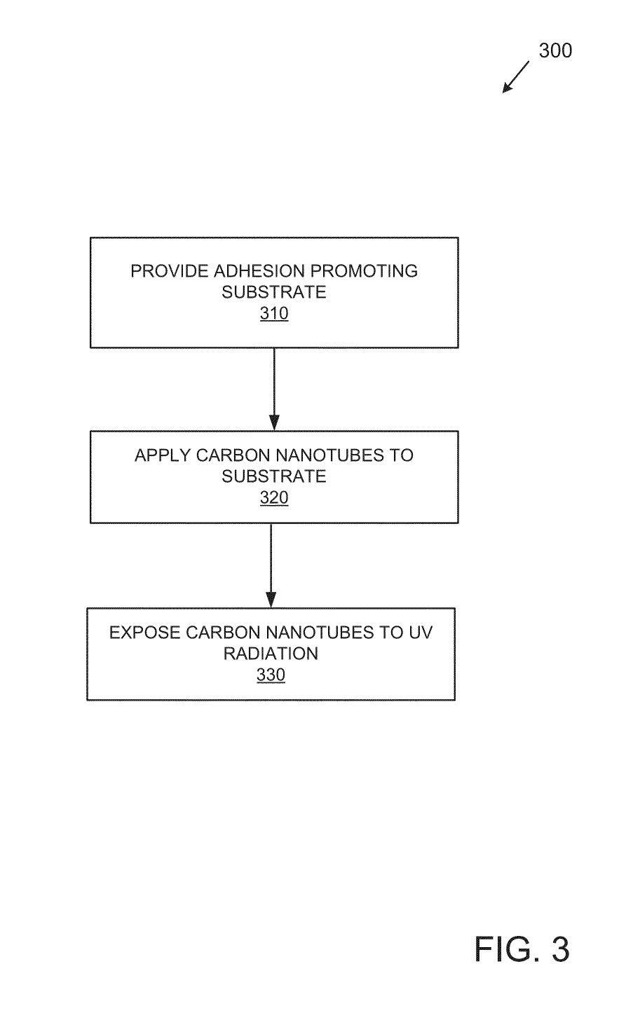

FIG. 3 is a representative method 300 of fabricating a carbon nanotube printed electronics device. At 310, an adhesion promoting substrate as described herein is provided. At 320, carbon nanotubes are applied to the adhesion promoting substrate to form a network of randomly aligned carbon nanotubes on the substrate. In some examples, the carbon nanotubes are contained in an ink, and the carbon nanotube ink is printed, drop-cast, spin-cast or otherwise deposited onto a surface of the substrate. Preferably, the surface of the substrate is not modified with any adhesion promoting solution to prepare for the nanotube deposition. For example, an adhesion promoting solution is not applied to the surface of the substrate prior to the application of the nanotubes. At 330, the carbon nanotubes are exposed to UV radiation to convert metallic carbon nanotubes into semiconductive carbon nanotubes.

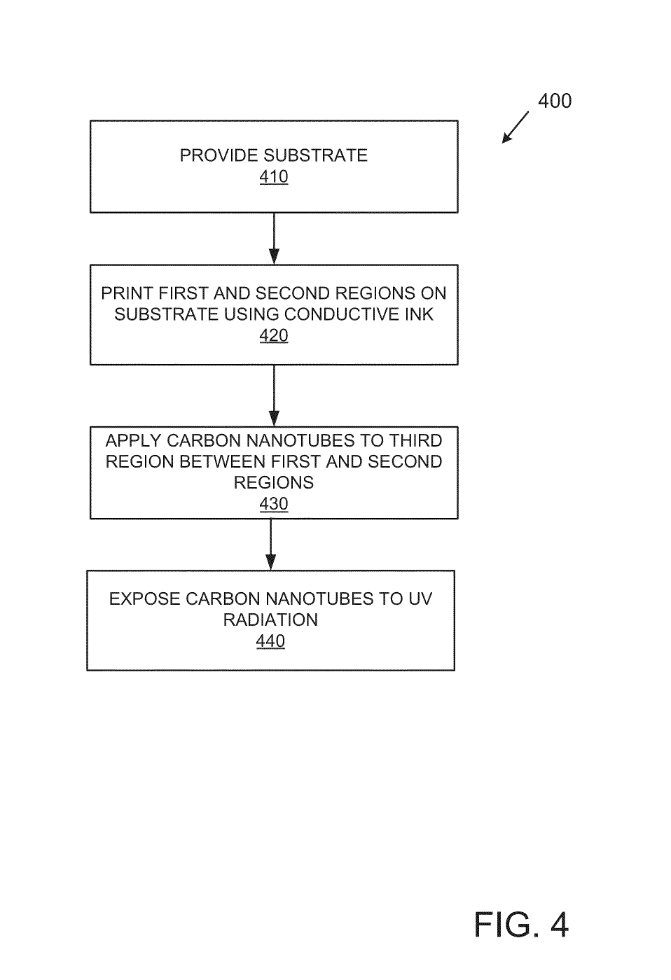

FIG. 4 is a representative method 400 of fabricating a carbon nanotube printed electronics device. At 410, a substrate is provided. The substrate can be any substrate described herein. At 420, first and second regions are printed on the substrate using conductive ink. For example, the regions can be printed using inkjet printing, gravure printing or other printing techniques described herein. At 430, carbon nanotubes are applied to a third region between the first and the second regions, to form a network of randomly aligned carbon nanotubes connecting the first region to the second region. In some examples, the carbon nanotubes are contained in an ink, and the carbon nanotube ink, either diluted or undiluted, is printed, drop-cast, spin-cast or otherwise deposited onto a surface of the substrate between the first and the second regions. Preferably, the surface of the substrate is not modified with any adhesion promoting solution to prepare for nanotube deposition. At 440, the carbon nanotubes are exposed to UV radiation to convert metallic carbon nanotube into semiconductive carbon nanotubes.

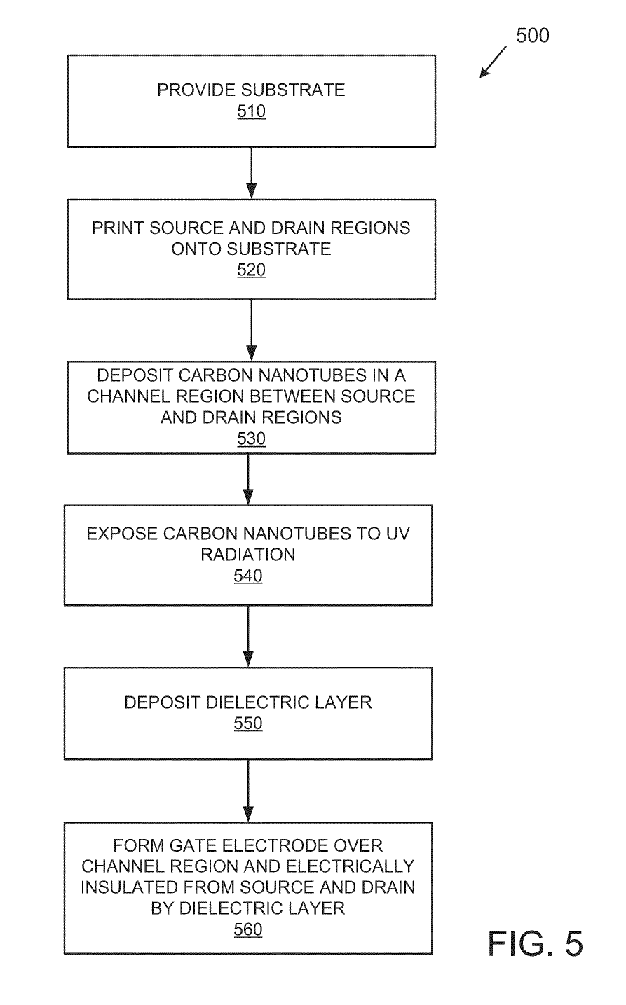

FIG. 5 is a representative method 500 of fabricating a carbon nanotube printed electronics device. At 510, a substrate is provided. The substrate can be any substrate described herein. At 520, source and drain region are printed onto the substrate. For example, the regions can be printed using conductive ink and inkjet printing, gravure printing or other printing techniques described herein. At 530, carbon nanotubes are deposited in a channel region between the source and the drain regions to form a network of randomly aligned carbon nanotubes. In some examples, the carbon nanotubes are contained in an ink, and the carbon nanotube ink, either diluted or undiluted, is printed, drop-cast, spin-cast or otherwise deposited onto a surface of the substrate between the source and the drain regions.

At 540, the carbon nanotubes are exposed to UV radiation to convert metallic carbon nanotubes into semiconductive carbon nanotubes. At 550, a dielectric layer is deposited. For example, any dielectric material can be deposited using techniques such as spin-coating or printing. However, other techniques can be used. At 560, a gate electrode is formed over the channel region and electrically insulated from the source and drain regions by the dielectric layer. For example, the gate electrode can be drop-cast or printed onto the dielectric layer.

For methods described herein, carbon nanotubes can be deposited or applied to a surface to form a network of randomly aligned carbon nanotubes using any known techniques. For example, carbon nanotube ink or other solution containing carbon nanotubes can be deposited or applied to the surface. Carbon nanotube ink can be diluted before it is deposited. For example, the carbon nanotube ink can be partially diluted with DI water. The carbon nanotube ink can be rinsed from the substrate after a period of time (e.g., a predetermined soak time). The carbon nanotube ink can be allowed to soak on the surface for any length of time.

In general, the dilution of the carbon nanotube ink and the soak time are selected based on the desired resistance or density of the resulting carbon nanotube network. For example, longer soak times typically result in the deposition of more carbon nanotubes, which leads to a denser network of carbon nanotubes. Density of the network can impact the electron/hole mobility of the network and the on/off ratio for a transistor including such a network. For example, increased density can increase mobility (e.g., increasing the number of metallic carbon nanotubes can increase mobility) and decrease on/off ratio. Therefore it can be preferable to dilute the ink and to allow the ink to soak for a short period of time. For example, the ink can be allowed to soak for about 1 second or less than 1 second. In other examples, the ink is allowed to soak for between about 1 second and about 5 seconds, between about 2 seconds and about 8 seconds, between about 3 seconds and about 10 seconds, between about 5 seconds and about 15 seconds, or more than 15 seconds.

The resistance of the carbon nanotube network can be measured by applying a voltage drop across the network. For example, the carbon nanotubes can be situated so as to form a network electrically connecting two conductive regions, and the resistance can be measured by applying a voltage to one of the conductive regions and measuring a current through the other conductive region. For example, the resistance of the carbon nanotube network can be measured by applying a voltage between first and second conductive regions, or between source and drain regions, that are electrically connected to the network. The light transparency (e.g., light absorption) of the carbon nanotube network can also be measured to evaluate network density.

Typically, it is preferable that the carbon nanotube network have a high resistance. For example, if the carbon nanotube network is deposited in a channel region of a transistor, a high resistance network is preferable so that voltage applied to a gate electrode can be used to modulate current flow between source and drain regions via the carbon nanotube network. For example, a resistance between about 50 and about 300 kΩ, between about 100 and about 500 kΩ, between about 200 and about 1000 kΩ, or greater than about 500 kΩ can be desirable.

For methods described herein, carbon nanotubes are exposed to UV radiation for any length of time. In general, the longer the carbon nanotubes are exposed to the UV radiation, the more conversion is achieved. For example, the carbon nanotubes can be exposed to UV radiation for about 2 hours, about 2.5 hours, about 3 hours, about 4 hours, or longer than 4 hours. In some examples, the carbon nanotubes are exposed to UV radiation for at least 1 hour, at least 2 hours, at least 4 hours or at least 6 hours. However, similar conversion may be achieved for lower exposure times when a UV source with higher power is used. For example, by increasing the intensity of UV radiation applied to the carbon nanotubes, the exposure time can be reduced. In general, it is preferable to reduce the number of metallic carbon nanotubes and to maximize the number of semiconductive carbon nanotubes in the carbon nanotube network. Carbon nanotube networks that have been exposed to UV radiation to convert metallic carbon nanotubes into semiconductive carbon nanotubes can be referred to as purified carbon nanotube networks.

It is typically preferable that the carbon nanotube network have a high resistance. A network composed of a mixture of metallic and semiconductive nanotubes will increase in resistance as the concentration of metallic nanotube is decreased. Therefore, the resistance of the carbon nanotube network can be measured and used as an indicator of the ratio of metallic to semiconductive nanotubes.

In some examples, the resistance of the carbon nanotube network after the application of UV radiation is about 1.5 times, 2 times, 2.5 times, 3 times, 3.5 times, 4 times or more than 4 times greater than the resistance of the carbon nanotube network before the application of UV radiation. For example, the resistance of the carbon nanotube network after the application of UV radiation can be between about 75 and about 450 kΩ, between about 150 and about 750 kΩ, between about 300 and about 1500 kΩ, between about 500 and about 1000 kΩ, between about 700 and about 1500 kΩ, or greater than about 750 kΩ. For example, the carbon nanotubes can be situated so as to form a network electrically connecting two conductive regions, and the resistance can be measured by applying a voltage to one of the conductive regions and measuring a current through the other conductive region.

In some examples, about 99 percent or less of the network of randomly aligned carbon nanotubes are semiconductive nanotubes before the applying of the UV radiation, and more than about 99 percent of the plurality of randomly aligned carbon nanotubes are semiconductive nanotubes after the applying of the UV radiation. For example, the network after the UV radiation is applied can include greater than about 99.1%, 99.2%. 99.3%, 99.4%, 99.5%, 99.6%, 99.7%, 99.8% or 99.9% semiconductive carbon nanotubes. Or, the network after the UV radiation is applied can include between about 99.1% and about 99.4%, about 99.2% and about 99.5%, about 99.3% and about 99.6%, about 99.4% and about 99.7%, about 99.5% and about 99.8%, or about 99.6% and about 99.9% semiconductive carbon nanotubes.

In some examples, the application of the UV radiation increases the proportion of photo-oxidized carbon nanotubes in the randomly aligned carbon nanotube network. For example, the network can have substantially no photo-oxidized carbon nanotubes before the application of UV radiation. In other examples, the network after the UV radiation is applied, includes at least about 0.1%, 0.2%, 0.3%, 0.4%, 0.5%, 0.6%, 0.7% 0.8%, or 0.9% photo-oxidized carbon nanotubes. In other examples, the network after the UV radiation is applied includes between about 0.1% and about 0.4%, between about 0.2% and about 0.5%, between about 0.3% and about 0.6%, between about 0.4% and about 0.7%, between about 0.5% and about 0.8%, between about 0.6% and about 0.9%, or greater than 0.9% photo-oxidized carbon nanotubes.

The increase in photo-oxidized carbon nanotubes in the network can be measured through various known methods. For example, the Raman spectra of the network can be measured before and after the application of the UV radiation. Measured Raman spectra can be indicative of the presence of oxygen functionalities on the nanotube sidewall. For example, after application of UV radiation, the network can exhibit an upshift in the Raman G band emission frequency and a decrease in the ratio of the Raman G band peak intensity to the Raman D band peak intensity relative to before the application of UV radiation. Further, after the application of UV radiation, Raman radial breathing mode (RMB) can be reduced or eliminated relative to before the application of UV radiation.

Methods described herein can include additional steps not recited in the figures. For example, additional methods of purifying nanotubes can be employed, e.g., electrical breakdown method or post-deposition etching.

The methods 300, 400 and 500 can be performed without annealing. For example, the methods 300, 400 and 500 can be performed without increasing the temperature above about 30° C., 40° C., 50° C., 100° C., 200° C., 400° C., 600° C. or 800° C. In some examples, the methods 300, 400 and 500 are performed at room temperature. That is, the methods 300, 400 and 500 are performed in an environment having a temperature less than about 20° C., 25° C., 30° C., 40° C., 50° C., 60° C., 70° C., 80° C., 90° C., or 100° C. As referred to herein, temperature can be the temperature of the air surrounding the substrate and carbon nanotube network, or it can be the temperature of the substrate and/or the carbon nanotube network.

In some examples, the methods 300, 400 and 500 are performed at non-vacuum atmospheric pressures. For example, the methods 300, 400 and 500 can be performed in atmospheric pressure greater than about 10 kPa, 30 kPa, 50 kPa, 70 kPa, 80 kPa, or 90 kPa. For example, the pressure can be between about 90 kPa and about 110 kPa, between about 70 kPa and about 100 kPa, between about 50 kPa and about 100 kPa, or at approximately 100 kPa, or at standard atmospheric pressure. In some examples, at least 330, 440, and/or 540 is performed in an oxygen enriched environment.

Carbon nanotube printed electronics devices described herein can have several advantages or benefits. For example, carbon nanotube printed electronics devices described herein can be fabricated at a relatively low cost and with relatively low cost printing techniques such as by using an ink jet printer. Further, fabrication processes described herein can be performed entirely at room temperature or near to room temperature conditions. Additionally, flexible, transparent substrates can be used. Such a versatile fabrication process can be readily adapted to numerous different substrates (e.g., “transistor's on anything”), and readily scaled to meet the demands of large area electronic system manufacturing. For example, devices and techniques described herein can be applied to produce electronics devices even on living tissues for bio-sensing applications.

Further, because fabrication processes described herein can be performed without an adhesion promotor, use of these caustic and toxic chemicals can be avoided, which is a benefit for the environment. Additionally, carbon nanotube printed electronics devices described herein can provide improved performance over current printed electronic devices, such as faster switching low power transistors.

Carbon nanotube printed electronics devices described herein can be used in various applications, such as any application that uses transistors or two-terminal devices. Example applications include RFID tags, data storage, displays, logic circuits. However, this list is non-exclusive.

### Example Implementation

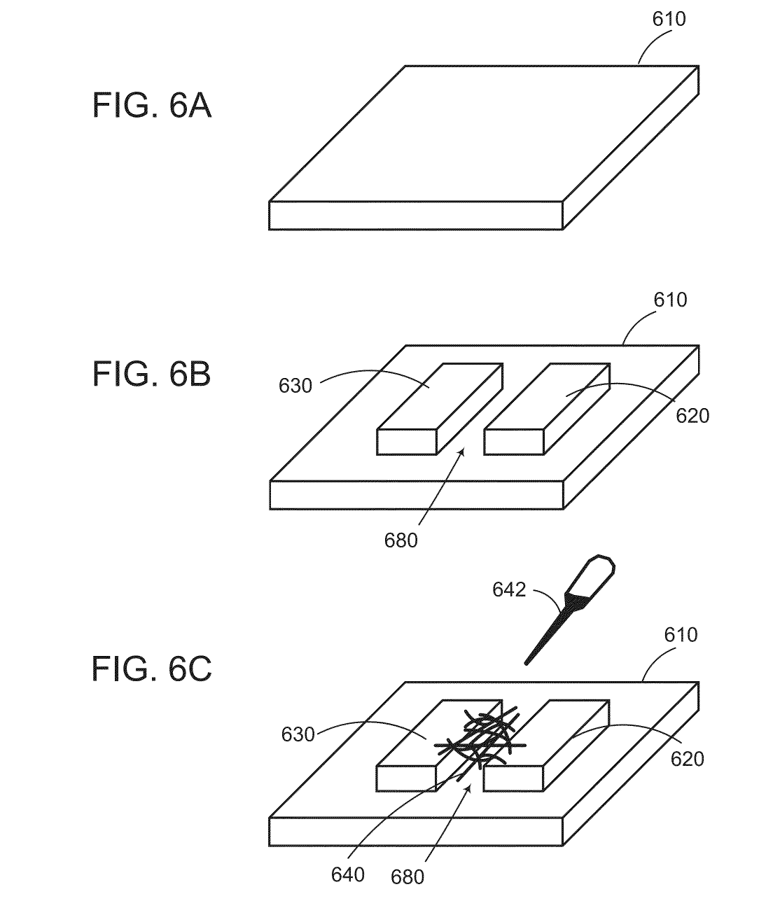

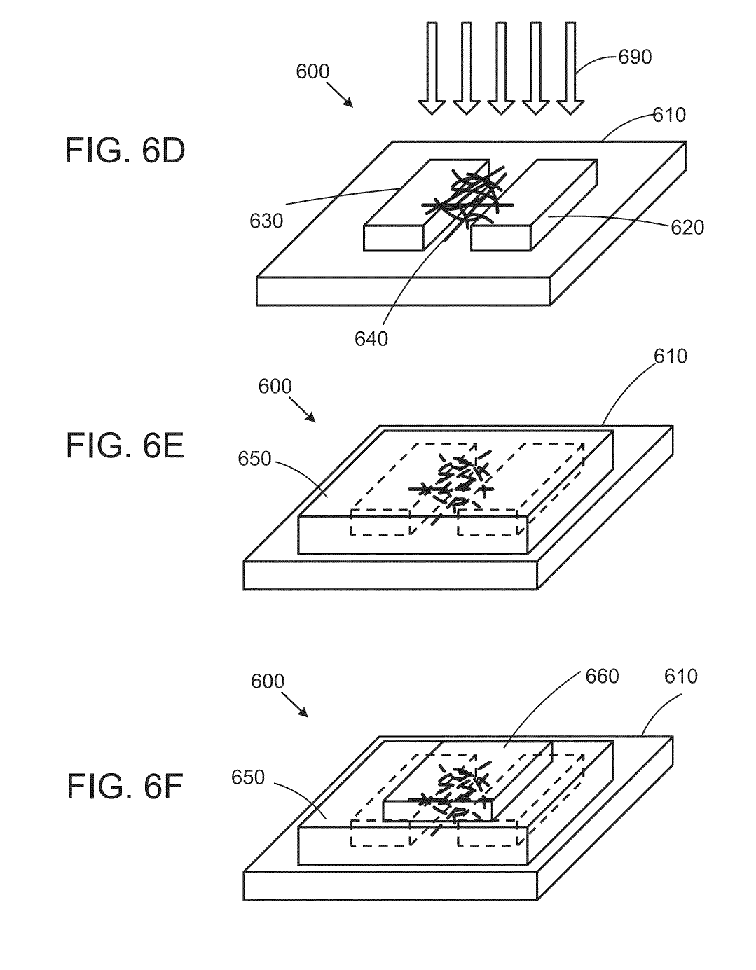

FIGS. 6A-6F illustrate stages in an exemplary fabrication of a carbon nanotube printed electronics device 600. FIG. 6A illustrates a first stage and shows a substrate 610. In this implementation, the substrate 610 is a sheet of polyethylene terephthalate (PET). FIG. 6B shows a source region 630 and a drain region 620 separated by a channel region 680 and situated on the substrate 610. In this implementation, the regions 630 and 620 are conductive regions that were printed onto the PET substrate 610 using an inkjet printer (Epson C88+) and silver nanoparticle ink. The regions 630 and 620 were about 0.5 micron thick and electrically conductive as printed, and no annealing was performed.

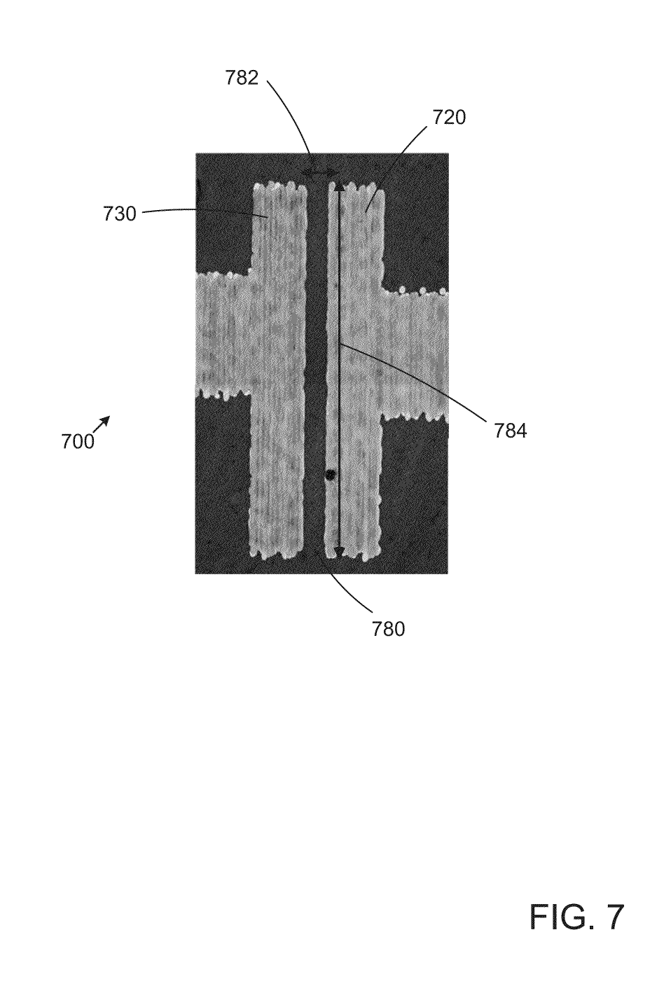

FIG. 7 is an image 700 of printed regions of an exemplary carbon nanotube printed electronics device. The image 700 shows a printed source region 730, a channel region 780, and a printed drain region 720. The channel region 780 has a length 782 and a width 784.

Referring to FIG. 6B, the source 630 and drain 620 regions were oriented along the direction of the paper feed of the inkjet printer. That is, the print head raster moved parallel to the channel width in order to provide a more uniform edge between the source region 630 and a drain region 620. In this implementation, the channel length 882 was about 130 microns and the channel width 884 was about 3620 microns.

FIG. 6C shows a plurality of carbon nanotubes 642 deposited onto the substrate 610 in the channel region 680 to form a network 640 of randomly aligned carbon nanotubes electrically connecting the source region 630 to the drain region 620. In this implementation, the plurality of carbon nanotubes 642 were deposited onto the substrate 610 by drop-casting carbon nanotube ink onto the channel region 680. The carbon nanotube ink was 99% pure semiconductive carbon nanotube ink. The carbon nanotubes had a range of diameters between about 1.2 nanometers and about 1.7 nanometers and a range of lengths between about 100 nanometers and about 4 microns. The mean length of the nanotubes was about 1 micron. The carbon nanotubes were suspended in water and diluted with DI water before drop-casting. The ink was applied to PET substrate without any adhesion promoter. That is, no adhesion promoting solution was applied to the PET before the nanotubes were drop-cast.

In this implementation, the carbon nanotube ink was allowed to soak on the surface of the substrate 610 for about 1 second. Then, the substrate 610 was rinsed with DI water and dried using nitrogen. The resulting network of carbon nanotubes 640 exhibited a resistance of between about 200 and 300 ohms.

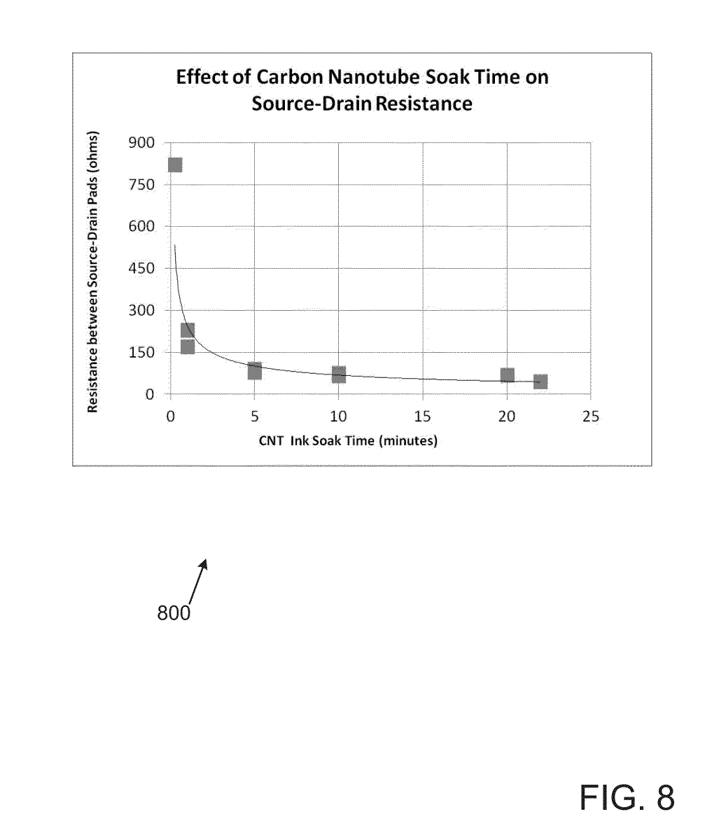

FIG. 8 shows resistance data 800 for several carbon nanotube networks. The networks were generated using a range of soak times from 1 second to 22 minutes and by drop-casting undiluted semiconductive carbon nanotube ink. The resistance of the carbon nanotube networks was measured by applying a voltage between the source and drain electrodes. As shown in the figure, the resistance of the carbon nanotube network varied from about 825 ohms for a 1 second soak time to about 50 ohms for a 20 minute soak time. As shown in FIG. 8, the resistance between the source and drain regions, across the network of randomly aligned carbon nanotubes, decreased as a function of soak time. The largest decrease in resistance occurred in the first 5 minutes of soak time, and the resistance eventually reached a saturation point.

FIG. 6D shows the application of UV radiation 690 to the network of randomly aligned carbon nanotubes 640. The UV radiation 690 converted metallic carbon nanotubes to semiconductive carbon nanotubes. In this implementation, the UV radiation 690 was from a UV lamp producing radiation having a range of wavelengths between about 365 nanometers and about 400 nanometers. The exposure time was 2 hours. In this implementation, for some samples, 680 kΩ resistance was measured for a voltage of 5V applied between the source 630 and the drain 620 after application of UV radiation 690 to carbon nanotube network, while for other samples 53 kΩ resistance was measured.

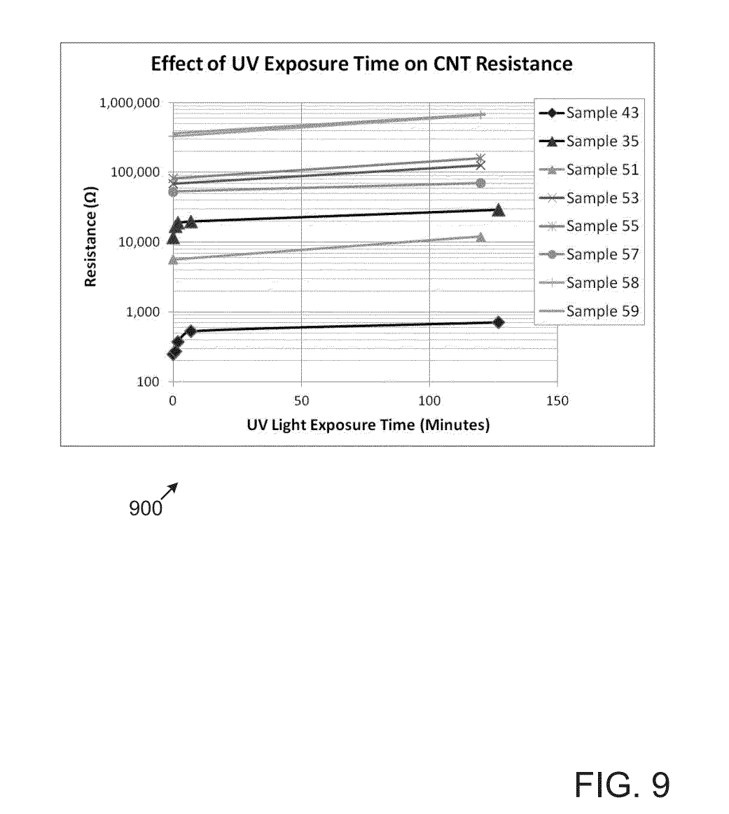

FIG. 9 shows resistance data 900 for several carbon nanotube networks exposed to UV radiation, each with different UV exposure times. The exposure times measured ranged from about 1 minute to about two hours. The resistance of the carbon nanotube networks was again measured by applying a voltage between the source and drain electrodes. As shown in FIG. 9, the resistance of the carbon nanotube networks was higher for longer UV radiation exposure times. UV exposure increased the resistance of the carbon nanotube networks by at least 2 to 3 times from the pre-exposure values. The resistance increased before saturating at about 3.5 times the starting value.

FIG. 6E shows a dielectric layer 650 situated on the substrate 610. In this implementation, the dielectric layer 650 was deposited by spin coating with polyimide (HD8820 by Hitachi) for one minute at 2000 rpm, then curing at room temperature for two hours.

FIG. 6F shows a gate region 660 situated on the dielectric layer 650. In this implementation, the gate region 660 was formed by drop casting PEDOT:PSS (poly(3,4-ethylenedioxythiophene) poly(styrenesulfonate)) (an organic conductor), that was allowed to dry at room temperature for about 30 minutes. In this implementation, hole mobility values of between about 31 and about 135 cm²/V-sec for operating voltages less than 2V and an ON/OFF ratio of about 14,620 were measured. In this implementation, all steps were performed at room temperature and without vacuum processing.

In view of the many possible embodiments to which the principles of the disclosed technology may be applied, it should be recognized that the illustrated embodiments are only preferred examples and should not be taken as limiting the scope of the disclosure. I claim all that comes within the scope and spirit of the appended claims.

1. An electronic device, comprising:
a first conductive region and a second conductive region; and
a network of purified and randomly oriented carbon nanotubes electrically coupled to the first and the second conductive regions, wherein the network of purified and randomly oriented carbon nanotubes comprises both metallic and semiconductive carbon nanotubes such that greater than about 99 percent of the carbon nanotubes in the network are semiconductive nanotubes.

2. The electronic device of claim 1, further comprising:
a substrate having a top surface and a bottom surface, wherein the first conductive region and the second conductive region are situated on the top surface and separated by a third region and at least a portion of the network of purified and randomly oriented carbon nanotubes is situated within the third region.

3. The electronic device of claim 2, wherein the substrate comprises a material selected from the following: a plastic, polyethylene terephthalate (PET), a flexible material, a material having a surface roughness that is between about 1 and 20 times an average diameter of the carbon nanotubes, and an adhesion promoting material.

4. The electronic device of claim 1, wherein the network of purified and randomly oriented carbon nanotubes is achieved by treating the network with UV radiation to convert metallic nanotubes into semiconductive nanotubes.

5. The electronic device of claim 1, wherein the network of purified and randomly oriented carbon nanotubes includes between about 99.5 percent and about 99.9 percent semiconductive nanotubes.

6. The electronic device of claim 2, wherein the first conductive region is a source region, the second conductive region is a drain region, the third conductive region is a channel region, the device is a transistor, and the transistor further comprises:
a dielectric layer situated so that the source region, the drain region, and the network of nanotubes are situated between the substrate and the dielectric layer; and
a gate electrode situated above the dielectric layer and the channel region and electrically insulated from the source region and the drain region by the dielectric layer.

7. The electronic device of claim 6, wherein the dielectric layer comprises polyimide.

8. The electronic device of claim 1, wherein the first and the second conductive regions comprise unannealed silver nanoparticle ink.

9. A logic circuit comprising a plurality of electronic devices according to claim 1.

10. A method of fabricating an electronic device, comprising:
depositing carbon nanotube ink including both metallic and semiconductive carbon nanotubes on a substrate to form a randomly aligned network of carbon nanotubes; and
applying UV radiation to the randomly aligned network of carbon nanotubes to convert some of the metallic carbon nanotubes into semiconductive carbon nanotubes.

11. The method of claim 10, wherein about 99 percent or less of the network of randomly aligned carbon nanotubes are semiconductive nanotubes before the applying of the UV radiation, and more than about 99 percent of the plurality of randomly aligned carbon nanotubes are semiconductive nanotubes after the applying of the UV radiation.

12. The method of claim 10, further comprising:
printing a first region using conductive ink;
printing a second region using conductive ink, wherein the randomly aligned network of carbon nanotubes electrically couples the first region to the second region.

13. The method of claim 12, wherein the printing of the first and the second regions is performed using an inkjet printer or gravure printing techniques.

14. The method of claim 12, wherein the printing, the depositing and the applying are performed in an atmospheric pressure between about 80 kPa and about 105 kPa and at a temperature less than about 100 degrees Celsius.

15. The method of claim 12, further comprising:
depositing a dielectric layer above the first region, the second region, and the network of randomly aligned carbon nanotubes; and
depositing a conductive material above the dielectric layer to form a gate electrode electrically insulated from the first and the second regions by the dielectric layer.

16. The method of claim 12, wherein a resistance of the randomly aligned network of carbon nanotubes between the first and the second regions after the application of the UV radiation is at least two times greater than a resistance of the randomly aligned network of carbon nanotubes between the first and the second regions before the application of the UV radiation.

17. A device, comprising:
an adhesion promoting substrate layer; and
a network of purified and randomly-oriented carbon nanotubes situated on the adhesion promoting substrate layer, wherein the network of purified and randomly oriented carbon nanotubes comprises between about 0.1% and about 0.9% photo-oxidized carbon nanotubes.

18. The device of claim 17, further comprising:
a plurality of pairs of printed source and drain regions comprising conductive ink, each pair of source and drain regions connected to each other by a network of nanotubes formed from the plurality of randomly-oriented carbon nanotubes.

19. The device of claim 17, wherein the substrate is selected from the following: a flexible material, polyethylene terephthalate (PET), or a plastic.

20. The device of claim 17, wherein the device contains no layer of adhesion promoter modified material.
